(19) United States
(12) Patent Application Publication
(10) Pub. No.: US 2006/0005745 A1
(43) Pub. Date: Jan. 12, 2006

(54) Method of producing a titanium-suboxide-based coating material, correspondingly produced coating material and sputter target provided there-with

(76) Inventors: Karl-Uwe Van Osten, Allersberg (DE); Klaus Dietrich, Nurnberg (DE); Wolfgang Schaff, Erlangen (DE); Ricarda Rix, Nurnberg (DE); Franz Jansen, Baesweiler (DE)

Correspondence Address: McGLEW AND TUTTLE, P.C., SCARBOROUGH STATION, SCARBOROUGH, NY, 10510-9227, US

(21) Appl. No.: 11/174,993

(22) Filed: Jul. 5, 2005

(30) Foreign Application Priority Data
Jul. 6, 2004 (DE) 10 2004 032 635.5

(51) Int. Cl. C04B 35/46; C09C 1/36; C23C 14/00

(52) U.S. Cl. 106/436; 501/134; 204/192.15; 204/192.22

(57) ABSTRACT

A method of producing a titanium-suboxide-based coating material comprises the following steps: providing a titanium-suboxide base material; and treating the titanium-suboxide base material under oxidizing conditions for in-situ development of a finely dispersed titanium-dioxide component in the ceramic titanium-suboxide base material.

### FIELD OF THE INVENTION

The invention relates to a method of producing a titanium-suboxide-based coating material as well as a coating material produced according to the method and a sputter target provided there-with.

### BACKGROUND OF THE INVENTION

The technical field of the present invention primarily involves the PVD coating technique, in which titanium dioxide is widely employed as coating material because of its high refraction index. Originally, proceeding from titanium metal as a coating material, a titanium dioxide layer was deposited, via a reactive PVD coating process by the addition of oxygen to the process gases, on a substrate to be coated. However, in coating based on metal targets, problems are posed by the very low coating rates in particular in the DC sputter process frequently used. This will slow down relevant manufacturing processes in the technical application, for example when PVD layer systems are applied for thermal insulation glazing.

To solve these problems, prior art suggestions consisted in using so-called suboxide targets on the basis of titanium or niobium suboxides.

These titanium suboxides of the chemical formula TiₙO₂ₙ₋₁, with n>2, are called Magneli phases. They have very positive properties as far as the use as a coating material is concerned, such as high corrosion resistance and excellent electric conductivity. Owing to their chemical composition, they are able strongly to accelerate layer production within the scope of the PVD coating technique.

Methods of producing these titanium-suboxide-based coating materials are known from lots of prior art documents such as DE 100 00 979 C1, U.S. Pat. No. 6,334,938 B2, U.S. Pat. No. 6,461,686 B1 and U.S. Pat. No. 6,511,587 B2. The production methods disclosed therein have in common that titanium dioxide is the starting material from which to proceed in the production of the titanium-suboxide-based coating material or the target as far as PVD-coating-technique is concerned; under reducing conditions, the starting material is transferred into a titanium suboxide either via a thermal sputtering process or corresponding sintering technology.

Drawbacks reside in the fact that comparatively strong fluctuations result in the stoichiometry of the coating materials thus produced, which is again accompanied with inconstant removal behaviour of the PVD coating material from the target produced. The reason resides in partially differing electric conductivity of the coating material in the case of varying stoichiometric compositions. Another drawback is a lower refraction index.

Special problems are posed by the influence of the respective oxygen content of the suboxide on the sputtering behaviour. If it fluctuates due to stoichiometric differences in the suboxide composition, this will result in a significant reduction of the sputtering rate. Tests have shown that removal rates of approximately 10 nm/min are obtained in sputter targets produced by reduced titanium dioxide.

Proceeding from the described prior art problems, it is an object of the invention to specify a method of producing a titanium-suboxide-based coating material as well as a coating material of that type, by the aid of which significantly high sputtering rates of the coating material are obtained without any relevant losses of the refraction index.

This object is fundamentally implemented by the titanium-suboxide-based coating material, as opposed to the state of the art, being produced starting from a titanium-suboxide base material that is further treated under oxidizing conditions. In doing so, a finely dispersed titanium-dioxide component is produced in situ in the titanium-suboxide base material.

Examinations of coating materials thus produced have shown that adhesions of titanium dioxide, in particular in the rutile phase thereof, positively affect the sputtering rate of the coating material and the refraction index of the coatings thus produced, provided this titanium-dioxide component is finely dispersedly integrated in a conductive matrix of electrically conductive suboxides such as Ti₃O₅, Ti₄O₇, Ti₅O₉, and Ti₈O₁₅. Thus the electric conductivity is not significantly affected. On the whole, the titanium-suboxide-based coating material produced by the method according to the invention excels by offering special advantages to DC sputtering, namely high electric conductivity, high density, high sputtering rates, good reproducibility, insignificant addition of oxygen as a process gas during sputtering, insignificant tendency of contamination of the target material upon the addition of oxygen as a process gas, high thermal resistance by homogeneous layer structuring in the target production, and a high achievable refraction index of the coatings produced from the coating material.

Fundamentally, any appropriate sintering process, for instance for the manufacture of a sintered-granulate coating material, suggests itself for the further treatment of the titanium-suboxide base material; however, the titanium-suboxide-based coating material is preferably produced by thermal sputtering of a titanium-suboxide base material, preferably with the aid of a multi-cathode plasma torch by the addition of oxygen. In doing so, the rutile phase of the titanium dioxide, at a proportion of up to maximally 50 percent by weight, is integrated in the titanium-suboxide-based coating material by oxidation of corresponding titanium-suboxide base materials. The rutile content can be controlled by way of the sputtering distance.

Titanium suboxides of the formula TiₙO₂ₙ₋₁, with n=3 to 8, have crystallized as preferred phases in the process.

Further features, details and advantages of the invention will become apparent from the ensuing description.

### DESCRIPTION OF THE PREFERRED EMBODIMENT

Producing a titanium-suboxide-based target proceeds from a titanium-suboxide base material in the form of a powder of a fineness that may be in a range between 10 and 200 μm. A radiographic, semiquantitative determination of the phase content of this material shows for example the following composition:
Ti₃O₅ 18 percent by weight
Ti₄O₇ 26 percent by weight
Ti₅O₉ 45 percent by weight
Ti₆O₁₁ 8 percent by weight
Ti₇O₁₃ 5 percent by weight
Ti₈O₁₅ 1 percent by weight

This sample was observed to contain comparatively well developed crystalline phases with very low amorphous components. Titanium dioxide could not be found so that the sum of crystalline suboxides was assumed to be 100 percent by weight. With only an approximate determination of the TiₙO₂ₙ₋₁ contents being possible in the quantification, listed above, of the individual suboxides because of the line overlap in the radiographic measurement diagram and because of the partially insignificant contents, the above listed approach results in a total of 103 percent.

This titanium-suboxide sputtering powder is sputtered thermally by a multi-cathode plasma torch—namely a triplex-II torch. This triplex-II torch is a three-cathode torch in which three stationary electrical arcs are produced.

That is what distinguishes this device from other thermal-sputtering plasma torches such as conventional single-cathode plasma torches, in which turbulences occur in the plasma jet, leading to the employed powder being worked irregularly. The important time and local fluctuations of the single arc negatively affect the melting behaviour and acceleration of the particles in the plasma beam, which also influences the efficiency of the coating process.

Upon thermal sputtering with the aid of the described multi-cathode plasma torch (details of which are specified in the specialist essays of Barbezat, G., Landes, K., “Plasmabrenner-Technologien-Triplex: Hohere Produktion bei stabilerem Prozeβ3”, in “Sulzer Technical Review”, edition 4/99, pages 32 to 35; and Barbezat, G., “Triplex II—Eine neue Ära in der Plasmatechnologie”, loc. cit., edition 1/2002, pages 20, 21) uniform, controlled treatment of the titanium-suboxide powder takes place, which is of substantial importance for setting a defined component of titanium dioxide in its rutile modification in situ. It is of decisive importance that the noble gas argon or a mixture of the noble gases argon and helium are used in the operation of the multi-cathode plasma torch for reduction of the titanium-suboxide base material in the torch to be prevented, thus enabling its controlled oxidation by the atmosphere. The coating material thus obtained excels by special chemical homogeneity. This special material nature, including the component, as specified, of rutile finely dispersed in a conductive titanium-suboxide matrix, results in clearly improved ability of sputtering of the coating material as compared to conventional titanium metal targets.

The following system parameters were used in the plasma sputtering process:
electric current: 450-520 A
plasma gas helium: 25-35 SLPM
plasma gas argon: 20-30 SLPM
sputtering distance: 80-120 mm
coating per passage: 20 μm
sputtering atmosphere: air

The coating material in the form of a titanium-suboxide-based sputtering layer, produced as explained above, comprises the following proportional composition, which was again determined semiquantitatively and radiographically:
rutile 41 percent by weight
Ti₃O₁₅ 15 percent by weight
Ti₄O₇ 10 percent by weight
Ti₅O₉ 9 percent by weight
Ti₆O₁₁ 9 percent by weight
Ti₇O₁₃ 5 percent by weight
Ti₈O₁₅ 11 percent by weight
(total of suboxides 59 percent by weight)

As regards the above table, it is stressed that the listed contents of the titanium-suboxide phases were determined semiquantitatively from the relative peak intensities of the radiographic measurement. Exclusively the crystalline phases were determined and converted to 100 percent by weight. Any definite quantification of the titanium suboxides is not possible, because there may be many combinations with a varying oxygen deficit.

For verification of the applicability of a titanium-suboxide-based coating material with a finely dispersed rutile component for use in dc-pulse magnetron sputters, PVD coating tests were made and compared to corresponding tests based on conventional Ti₄O₇-mixed-oxide targets.

The following system parameters were used:
target-substrate distance: 90 mm
target material: titanium-suboxide coating material with rutile or Ti₄O₇ mixed oxide, respectively
gas flow: 2×100 sccm/purity: 4.8
carrier rate: 0.5 mm/s

Set as process parameters were:
base pressure: approximately 3×10⁻⁶ mbar
substrate temperature: ambient temperature
discharge power: 2000-6000 W
generator frequency: 100 kHz
pulse time: 1 μs
mixed-gas flow (Ar: O₂W9:1): 0-100 sccm/purity: O₂4.5/Ar 5.0
total pressure: 500 mPa
substrate: float glasses 10×10 cm², 5×5 cm²

The mixed-gas flow with an addition of O₂ is necessary because of the under-stoichiometry in the coating material. Any modification of discharge voltage will not be found above a certain flow of oxygen, as a result of which there is no unsteady behaviour as usual in the sputtering of metal targets upon transition from the metal to the oxide mode. The ceramic suboxide targets according to the invention ensure more stable process management.

The following comparative table of the static sputtering rate as and the optical refraction index n for various titanium target materials shows that the inventive ceramic titanium-suboxide-based coating materials with rutile phase offer an optimal compromise of sputtering rate and refraction index.

The TiOₓ sputtering layer shows the highest sputtering rate as compared to the Ti₄O₇ mixed oxide target and the titanium target reactively sputterd in the transition mode. Only the refraction index of the titanium target sputtered in the oxide mode is higher, however at a sputtering rate that is lower by a factor of nearly 12.

TABLE
comparison of the static sputter rate aₛ and the optical refraction
index n for various titanium based target materials.

| | Rate aₛ at 1 W/cm² | |
|---|---|---|
| Material | [nm/min] | n at λ, = 550 nm |
| TiOₓ sputtering layer | 14.8 | 2.47 |
| Ti₄O₇ mixed oxide | 9.9 | 2.42 |
| Ti oxide mode | 1.2 | 2.51 |
| Ti transition mode | 6.3 | 2.42 |

1. A method of producing a titanium-suboxide-based coating material, comprising the following steps:
providing a titanium-suboxide base material; and
treating the titanium-suboxide base material under oxidizing conditions for in-situ development of a finely dispersed titanium-dioxide component in the ceramic titanium-suboxide base material.

2. A method according to claim 1, wherein the titanium-suboxide-based coating material is a PCD coating material and is produced by thermal sputtering of the titanium-suboxide base material by an addition of oxygen.

3. A method according to claim 1, wherein the titanium-suboxide-based coating material is produced by thermal sputtering of the titanium-suboxide base material, with reducing conditions being avoided by the use of noble gases upon plasma sputtering in atmosphere.

4. A method according to claim 1, wherein the titanium dioxide component is integrated as rutile in the titanium-suboxide-based coating material.

5. A method according to claim 1, wherein the finely dispersed titanium-dioxide component in the titanium-suboxide-based coating material amounts to maximally 50 percent by weight.

6. A method according to claim 1, wherein a mixed powder of titanium suboxides of a formula TiₙO₂n−₁, preferably with n=3 to 8, is used as titanium-suboxide base material.

7. A method according to claim 2, wherein the titanium-suboxide base material is thermally sputtered with the aid of a multi-cathode plasma torch.

8. A coating material, in particular electrically conductive PVD coating material, produced according to claim 1, comprising a titanium-dioxide component finely dispersed in a ceramic titanium-suboxide base material.

9. A coating material according to claim 8, wherein the titanium-dioxide component is a rutile.

10. A coating material according to claim 8, comprising titanium suboxides of a formula T1ₙ,0₂ₙ₋₁, preferably with n=3 to 8, as titanium-suboxide base material.

11. A coating material according to claim 8, wherein the finely dispersed titanium-dioxide component in the titanium-suboxide-based coating material amounts to maximally 50 percent by weight.

12. A coating material according to claim 8, wherein it is a fusion or sintered granulate.

13. A sputter target, comprising a coating material according to claim 8 on a substrate.

14. A sputter target according to claim 13, wherein it is a tubular cathode or planar target.

15. A sputter target, comprising a coating material according to claim 9 on a substrate.

16. A sputter target, comprising a coating material according to claim 10 on a substrate.

17. A sputter target, comprising a coating material according to claim 11 on a substrate.
